(19) United States
(12) Patent Application Publication
(10) Pub. No.: US 2008/0197929 A1
(43) Pub. Date: Aug. 21, 2008

(54) Resonant Types Of Common-Source/Common-Emitter Struture For High Gain Amplification

(75) Inventors: Mau-Chung Frank Chang, Los Angeles, CA (US); Daquan Huang, Dallas, TX (US)

Correspondence Address: LADAS & PARRY, 5670 WILSHIRE BOULEVARD, SUITE 2100, LOS ANGELES, CA, 90036-5679, US

(73) Assignee: THE REGENTS OF THE UNIVERSITY OF CALIFORNIA, Oakland, CA (US)

(21) Appl. No.: 11/996,582

(22) PCT Filed: Jul. 31, 2006
(86) PCT No.: PCT/US06/29970

§ 371 Date: Jan. 23, 2008

Related U.S. Application Data
(60) Provisional application No. 60/705,861, filed on Aug. 4, 2005.

(51) Int. Cl. H03F 3/16

(52) U.S. Cl. 330/277

(57) ABSTRACT

Radio frequency/millimeter wave integrated circuits (RF/MMICs) that employ a resonance mechanism between an input stage and a transistor are disclosed. The circuits contain an input stage, a transistor; and a transformer connected between either a gate or a base of the transistor and a voltage supply of the input stage. The methods disclosed maximize either a collector current or a drain current of a transistor by placing a transformer between the transistor and a voltage source.

### CROSS REFERENCE TO RELATED APPLICATION

This application claims the benefit of U.S. provisional patent application Ser. No. 60/705,861, filed Aug. 4, 2005 for a “Resonant Types of Common-Source/Common-Emitter Structure for High Gain Amplification” by Daquan Huang and Mau-Chung F. Chang, the disclosure of which is incorporated herein by reference in its entirety.

### STATEMENT REGARDING FEDERALLY SPONSORED RESEARCH OR DEVELOPMENT

The present invention was made with support from the U.S. Government under Grant number N66001-04-1-8934 awarded by the U.S. Navy. The United States Government has certain rights in the invention.

### FIELD

The present invention relates to amplification circuits. More particularly, the present invention relates to radio frequency/millimeter wave integrated circuits (RF/MMICs) that employ a resonance mechanism between an input stage and a transistor.

### BACKGROUND

Higher gain has always been desirable in amplification circuits, especially in radio frequency/millimeter wave integrated circuits (RF/MMICs).

In conventional radio frequency and millimeter wave circuit input stage designs, inductors are used such that they cancel the parasitic capacitances and match the input impedance to that of the signal source, aiming either to maximize the available power gain or to minimize the noise figure. However, in many analog and mixed-signal circuit designs, voltage gain is the only concern. Therefore, impedance matching is not the optimal design strategy.

To overcome this deficiency, the present disclosure presents a new design that employs a resonance mechanism to maximize a voltage gain.

### SUMMARY

According to the present disclosure, amplification circuits are disclosed.

According to a first embodiment disclosed herein, a circuit is disclosed, comprising: an input stage; a transistor; and a transformer connected between a gate of the transistor and a voltage supply of the input stage.

According to a second embodiment disclosed herein, a circuit is disclosed, comprising: an input stage; a transistor; and a transformer disposed between a base of the transistor and a voltage supply of the input stage.

According to a third embodiment disclosed herein, a method for maximizing a drain current of a transistor is disclosed, comprising: selecting a transistor; selecting a transformer; and connecting the transformer between a gate of the transistor and a voltage source.

According to a fourth embodiment disclosed herein, a method for maximizing a collector current of a transistor is disclosed, comprising: selecting a transistor; selecting a transformer; connecting the transformer between a base of the transistor and a voltage source.

### BRIEF DESCRIPTION OF THE FIGS.

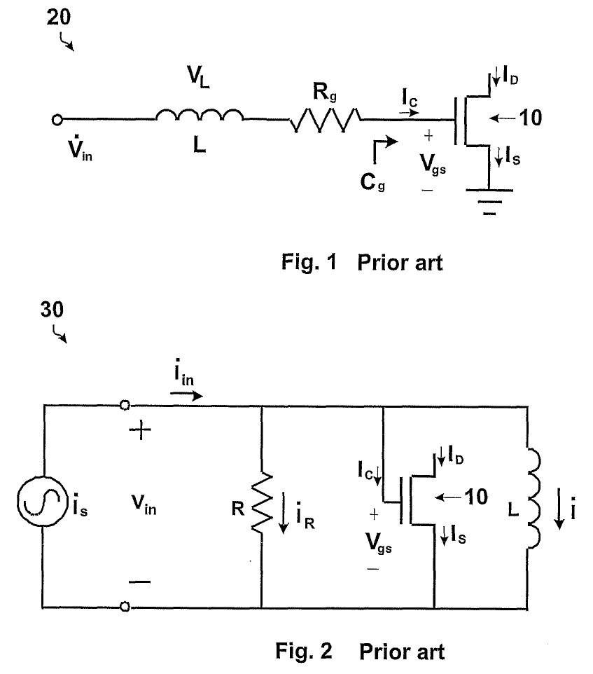

FIG. 1 depicts a series resonant common-source circuit as known in the Prior Art;

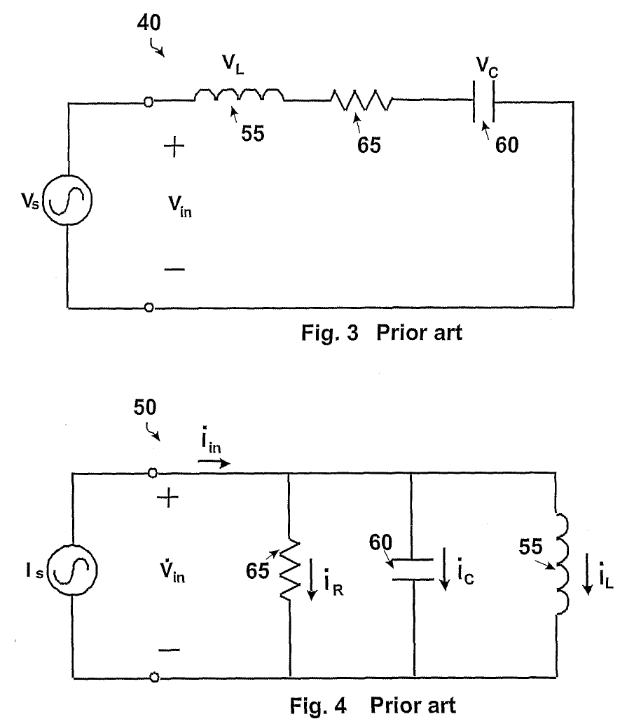

FIG. 2 depicts a parallel resonant common-source circuit as known in the Prior Art;

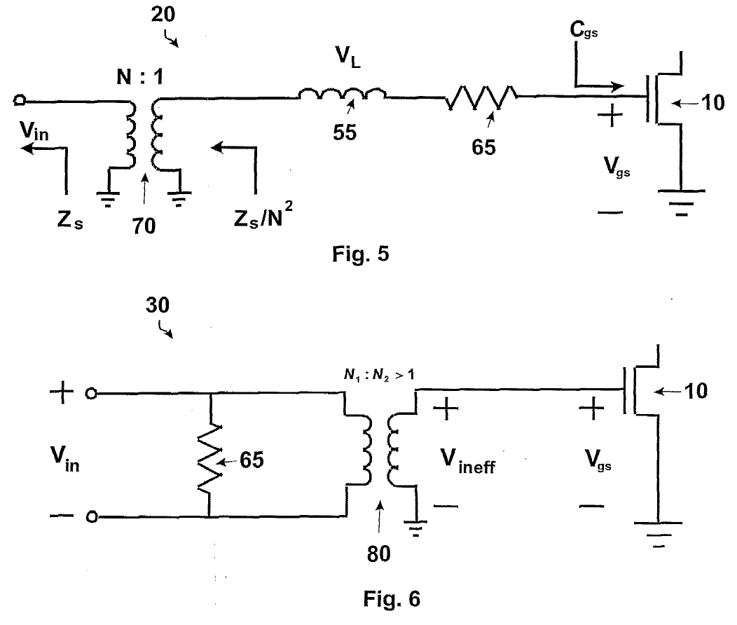

FIG. 3 depicts an electrically equivalent circuit of FIG. 1;

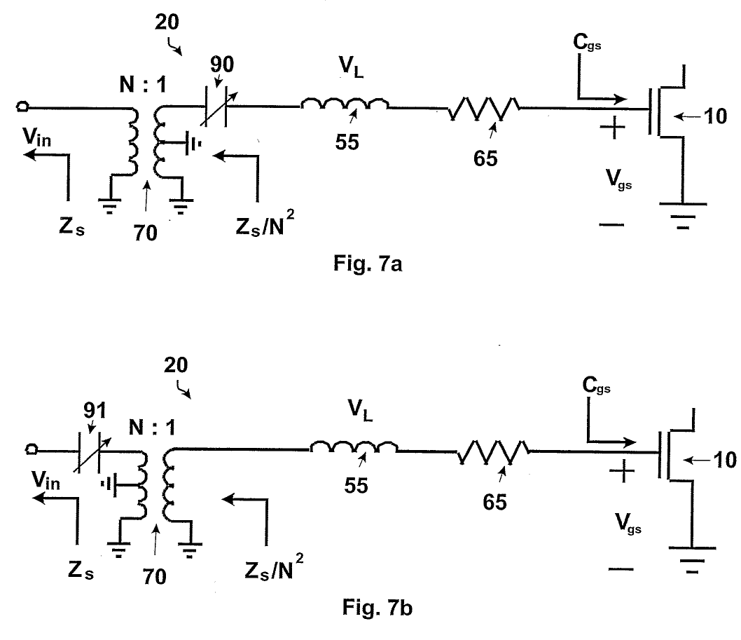

FIG. 4 depicts an electrically equivalent circuit of FIG. 2;

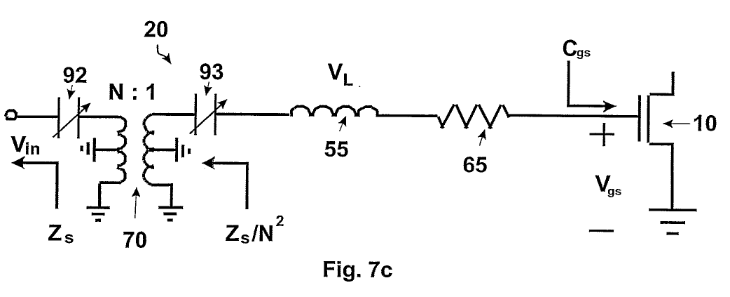

FIG. 5 depicts an embodiment of a series resonant common-source circuit according to the present disclosure;

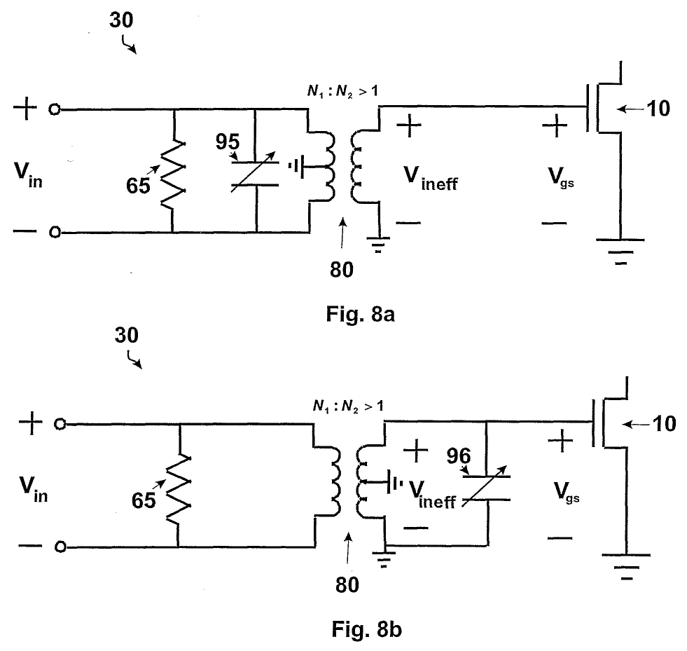

FIG. 6 depicts an embodiment of a parallel resonant common-source circuit according to the present disclosure;

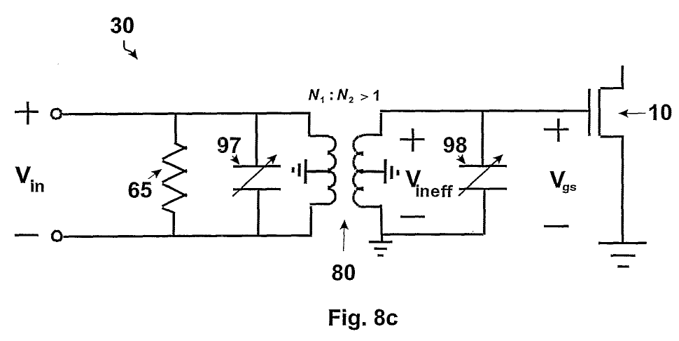

FIGS. 7a-c depict other embodiments of a series resonant common-source circuit according to the present disclosure;

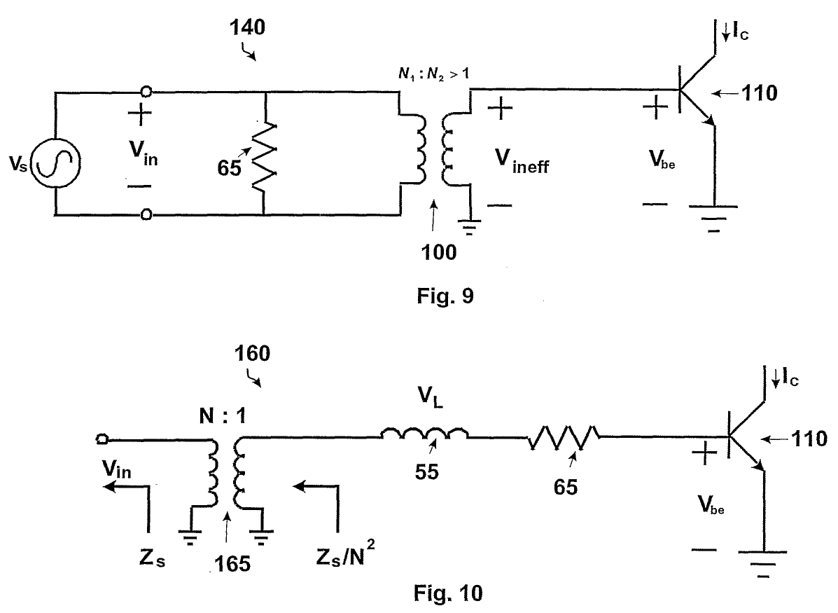

FIGS. 8a-c depict other embodiments of a parallel resonant common-source circuit according to the present disclosure;

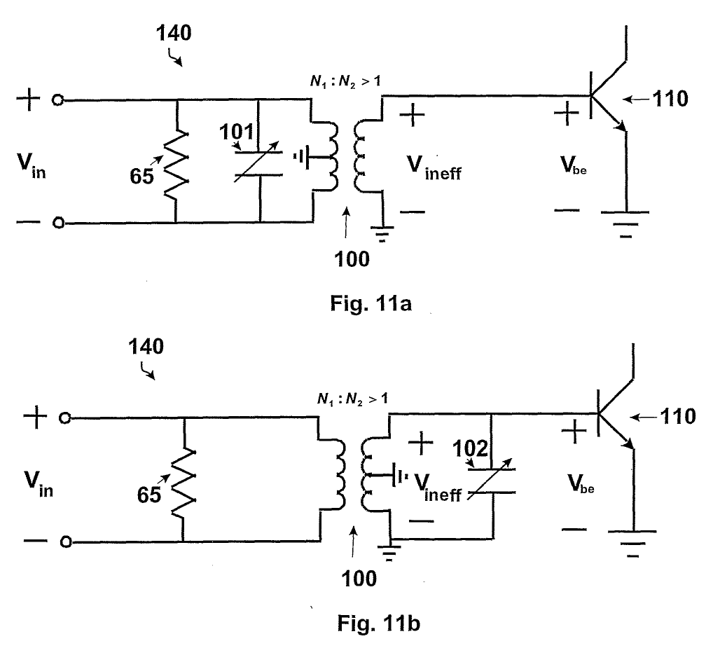

FIG. 9 depicts an embodiment of a parallel resonant common-emitter circuit according to the present disclosure;

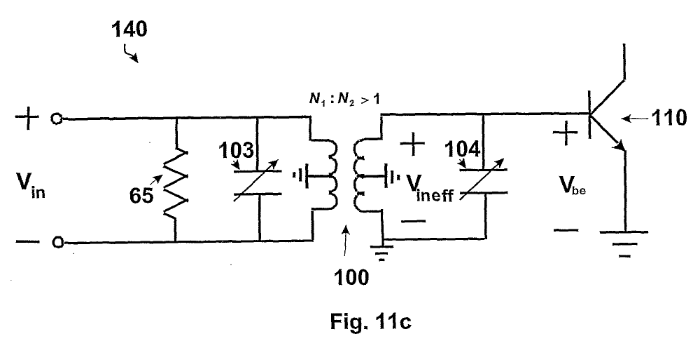

FIG. 10 depicts an embodiment of a series resonant common-emitter circuit according to the present disclosure;

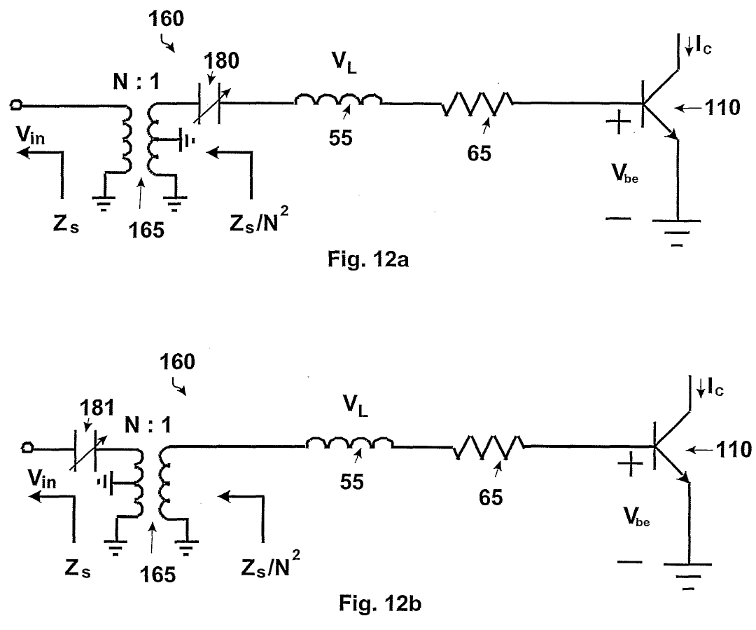

FIGS. 11a-c depicts other embodiments of a parallel resonant common-emitter circuit according to the present disclosure; and

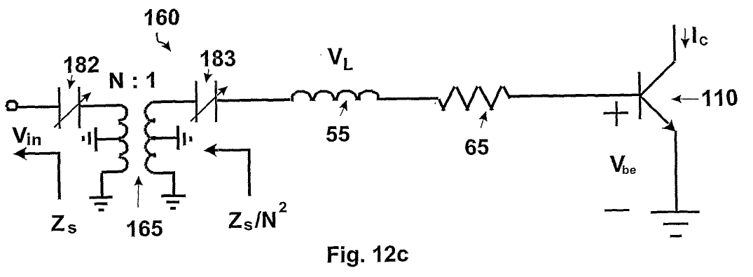

FIGS. 12a-c depicts other embodiments of a series resonant common-emitter circuit according to the present disclosure.

In the following description, like reference numbers are used to identify like elements. Furthermore, the drawings are intended to illustrate major features of exemplary embodiments in a diagrammatic manner. The drawings are not intended to depict every feature of every implementation nor relative dimensions of the depicted elements, and are not drawn to scale.

### DETAILED DESCRIPTION

According to prior art shown in FIGS. 1 and 2, MOS transistors 10 in common-source circuits 20 and 30 convert the input voltage V_{gs} into the drain current I_{D}, wherein I_{D} for NMOS transistor is

$${I}_{D} = \frac{{μ}_{n} {C}_{ox}}{2} \frac{W}{L} {( {V}_{gs} - {V}_{th} )}^{2} ;$$

I_{D} for PMOS transistor is

$${I}_{D} = \frac{{μ}_{p} {C}_{ox}}{2} \frac{W}{L} {( {V}_{gs} - {V}_{th} )}^{2} ;$$

μₙ is the mobility of electrons; μ_{P} is the mobility of holes; Cₒₓ is the gate oxide capacitance per unit area; W and L are the width and length of the gate; Vₜₕ is the threshold voltage; ω_{O} is resonant angular frequency determined by

$${ω}_{o} = \frac{1}{\sqrt{LC}} ;$$

Iₛ is the inverse saturation current; and V_{T} is the threshold voltage. As known in the art, increasing V_{gs} increases the output current I_{D} that determines the output voltage by Vₒᵤₜ=I_{D}Z_{O}, where Zₒ is the output impedance of the circuit. Therefore, maximizing V_{gs} maximizes the voltage gain.

The series resonant input circuit 40 and the parallel resonant input circuit 50 shown in FIGS. 3 and 4 are electrically equivalent to common-source circuits 20 and 30, respectively. As can be seen in FIGS. 3 and 4, capacitors 60 represent the transistor gate capacitance of the transistors 10 in common-source circuits 20 and 30.

In the series resonant input circuit 40, driven by voltage source V_{S}, as shown in FIG. 3, the voltage (V_{L} or V_{C}) on the reactance elements (the inductor 55 and the capacitor 60) is Q times higher than the input voltage Vᵢₙ, where Q is the quality factor (Q-factor) defined by Q=ω₀L/r=1/rω₀C;

$${ω}_{0} = \sqrt{\frac{1}{LC}} ;$$

V_{L}=jQVᵢₙ; V_{C}=jQVᵢₙ and variables L, C and r are the series inductance of the inductor 55, capacitance of the capacitor 60 and the parasitic resistance 65 respectively. Therefore, the input voltage Vᵢₙ is amplified by Q times when it is applied to the series resonant input circuit 40. However, the input voltage Vᵢₙ may further be amplified by providing a smaller signal source impedance in the series resonant input circuit 40 as discussed below.

In the parallel resonant input circuit 50, driven by a current source I_{S} as shown in FIG. 4, the current (I_{L} or I_{C}) of the reactance elements (the inductor 55 and the capacitor 60) is Q times larger than the input current Iᵢₙ, where Q=R/ω₀L=Rω₀C;

$${ω}_{0} = \sqrt{\frac{1}{LC}} ;$$

IL_{L=jQV}ᵢₙ; I_{C}=jQVᵢₙ and variables L, C and R are the parallel inductance of the inductor 55, capacitance of the capacitor 60 and the parasitic resistance 65. Therefore, I_{L} is Q times larger than the input current Iᵢₙ.

In one exemplary embodiment, the present disclosure amplifies the input voltage Vᵢₙ of the common-source circuit 20 by employing a resonance mechanism like a transformer 70, for example, to reduce the signal source impedance Z_{S} by 1/N² in the common-source circuit 20, as shown in FIG. 5. By reducing the signal source impedance Z_{S} using the transformer 70, a higher Q-factor, Q=ω₀L/real(Z_{S}IN²)=1/real(Z₂IN²)ω₀C, is obtained.

In another exemplary embodiment, the present disclosure amplifies the transistor 10's input voltage V_{gs} of the common-source circuit 30 by employing a resonance mechanism like a transformer 80, for example, with the primary to secondary coil turn ratio N₁:N₂>1 in the common-source circuit 30, as shown in FIG. 6.

In another exemplary embodiment, a variable capacitor device 90 like, for example, a varactor, disposed between the transformer 70 and the transistor 10 may be used to adjust the resonant frequency of the common-source circuit 20, as shown in FIG. 7a. The resonant frequency may be determined by

$${f}_{ο} = \frac{1}{2 π} \frac{1}{\sqrt{{LC}^{′}}}$$

where C includes capacitance of variable capacitor device 90 and inductor/transformer parasitic capacitance.

Similarly, a variable capacitor device 91 like, for example, a varactor, disposed between the transformer 70 and Vᵢₙ may be used to adjust the resonant frequency of the common-source circuit 20, as shown in FIG. 7b.

Also, variable capacitor device 92, disposed between the transformer 70 and Vᵢₙ, together with a variable capacitor devices 93, disposed between the transformer 70 and the transistor 10 may also be used to adjust the resonant frequency of the common-source circuit 20, as shown in FIG. 7c.

In another exemplary embodiment, a variable capacitor device 95 like, for example, a varactor, disposed between the transformer 80 and the input voltage Vᵢₙ, may be used to adjust the resonant frequency of the common-source circuit 30, as shown in FIG. 8a.

Similarly, a variable capacitor device 96 like, for example, a varactor, disposed between the transformer 80 and the transistor 10 may be used to adjust the resonant frequency of the common-source circuit 30, as shown in FIG. 8b.

Also, variable capacitor device 97, disposed between the transformer 80 and Vᵢₙ, together with a variable capacitor devices 98, disposed between the transformer 80 and the transistor 10 may also be used to adjust the resonant frequency of the common-source circuit 30, as shown in FIG. 8c.

In another exemplary embodiment, teachings of the present disclosure may be applied to common-emitter circuit 140 using bipolar technology as shown in FIGS. 9 and 10.

A bipolar transistor 110 in the common-emitter circuit 140 converts the input voltage V_{be} into the collector current I_{C}, wherein

$${I}_{C} = {I}_{S} exp ( \frac{{V}_{BE}}{{V}_{T}} ) .$$

As known in the art, increasing V_{be} increases the output current I_{C} that in turn yields higher voltage gain. Therefore, employing a resonance mechanism like a transformer 100, for example, with the primary to secondary coil turn ratio N₁:N₂>1 in the common-emitter circuit 140, as shown in FIG. 9 amplifies the transistor 110's input voltage V_{be} of the common-emitter circuit 140.

Similarly, employing a resonance mechanism like a transformer 165, for example, in the common-emitter circuit 160, as shown in FIG. 10 also amplifies the transistor 110's input voltage V_{bc} of the common-emitter circuit 160.

In another exemplary embodiment, a variable capacitor device 101 like, for example, a varactor, disposed between the transformer 100 and the input voltage Vᵢₙ may be used to adjust the resonant frequency of the common-emitter circuit 140, as shown in FIG. 10a.

Similarly, a variable capacitor device 102 like, for example, a varactor, disposed between the transformer 100 and the transistor 110 may be used to adjust the resonant frequency of the common-emitter circuit 140, as shown in FIG. 10b.

Also, variable capacitor device 103, disposed between the transformer 100 and Vᵢₙ, together with a variable capacitor devices 104, disposed between the transformer 100 and the transistor 110 may also be used to adjust the resonant frequency of the common-emitter circuit 140, as shown in FIG. 10c.

In another exemplary embodiment, a variable capacitor device 180 like, for example, a varactor, disposed between the transformer 165 and the transistor 110 may be used to adjust the resonant frequency of the common-emitter circuit 160, as shown in FIG. 11a.

Similarly, a variable capacitor device 181 like, for example, a varactor, disposed between the transformer 165 and Vᵢₙ, may be used to adjust the resonant frequency of the common-emitter circuit 160, as shown in FIG. 11b.

Also, variable capacitor device 182, disposed between the transformer 165 and Vᵢₙ, together with a variable capacitor devices 183, disposed between the transformer 165 and the transistor 110 may also be used to adjust the resonant frequency of the common-emitter circuit 160, as shown in FIG. 11c.

The foregoing detailed description of exemplary and preferred embodiments is presented for purposes of illustration and disclosure in accordance with the requirements of the law. It is not intended to be exhaustive nor to limit the invention to the precise form(s) described, but only to enable others skilled in the art to understand how the invention may be suited for a particular use or implementation. The possibility of modifications and variations will be apparent to practitioners skilled in the art. No limitation is intended by the description of exemplary embodiments which may have included tolerances, feature dimensions, specific operating conditions, engineering specifications, or the like, and which may vary between implementations or with changes to the state of the art, and no limitation should be implied therefrom. Applicant has made this disclosure with respect to the current state of the art, but also contemplates advancements and that adaptations in the future may take into consideration of those advancements, namely in accordance with the then current state of the art. It is intended that the scope of the invention be defined by the Claims as written and equivalents as applicable. Reference to a claim element in the singular is not intended to mean “one and only one” unless explicitly so stated. Moreover, no element, component, nor method or process step in this disclosure is intended to be dedicated to the public regardless of whether the element, component, or step is explicitly recited in the claims. No claim element herein is to be construed under the provisions of 35 U.S.C. Sec. 112, sixth paragraph, unless the element is expressly recited using the phrase “means for . . . ” and no method or process step herein is to be construed under those provisions unless the step, or steps, are expressly recited using the phrase “step(s) for . . . ”

What is claimed is:

1. A circuit comprising:
an input stage;
a transistor; and
a transformer connected between a gate of the transistor and a voltage supply of the input stage.

2. The circuit of claim 1, wherein the transistor is a MOS transistor.

3. The circuit of claim 1, the input stage is a series resonant circuit.

4. The circuit of claim 1, the input stage is a parallel resonant circuit.

5. The circuit of claim 4, wherein the transformer has a primary to secondary coil turn ratio N₁:N₂>1.

6. The circuit of claim 1, further comprising a variable capacitance device connected to the circuit for controlling an operating frequency of the circuit

7. The circuit of claim 6, wherein the variable capacitance device is a varactor.

8. A circuit comprising:
an input stage;
a transistor; and
a transformer disposed between a base of the transistor and a voltage supply of the input stage.

9. The circuit of claim 8, wherein the transistor is a MOS transistor.

10. The circuit of claim 8, wherein the transistor is a bipolar transistor.

11. The circuit of claim 8, the input stage is a series resonant circuit.

12. The circuit of claim 8, the input stage is a parallel resonant circuit.

13. The circuit of claim 12, wherein the transformer has a primary to secondary coil turn ratio N₁:N₂>1.

14. The circuit of claim 8, further comprising a variable capacitance device connected to the circuit for controlling an operating frequency of the common-emitter structure.

15. The circuit of claim 14, wherein the variable capacitance device is a varactor.

16. A method for maximizing a drain current of a transistor comprising:
selecting a transistor;
selecting a transformer; and
connecting the transformer between a gate of the transistor and a voltage source.

17. The method of claim 16, wherein the transistor is a MOS transistor.

18. The method of claim 16, further comprising adjusting an operating frequency of a transistor with a variable capacitance device.

19. The method of claim 18, wherein the variable capacitance device is a varactor.

20. A method for maximizing a collector current of a transistor comprising:
selecting a transistor;
selecting a transformer;
connecting the transformer between a base of the transistor and a voltage source.

21. The method of claim 20, wherein the transistor is a bipolar transistor.

22. The method of claim 20, wherein the transformer has a primary to secondary coil turn ratio N₁:N₂>1.

23. The method of claim 20, further comprising adjusting an operating frequency of the transistor with a variable capacitance device.

24. The method of claim 23, wherein the variable capacitance device is a varactor.
